(19) United States
(12) Patent Application Publication
(10) Pub. No.: US 2025/0207260 A1
(43) Pub. Date: Jun. 26, 2025

(54) METHOD AND INSTALLATION FOR PLASMA COATING

(71) Applicant: CCR GmbH, Beschichtungstechnologie, Troisdorf (DE)

(72) Inventors: Valbon DAUT, Troisdorf (DE); Mohammed RAZOUKI, Troisdorf (DE); Steffen HEUSER, Troisdorf (DE)

(21) Appl. No.: 18/847,721

(22) PCT Filed: Dec. 5, 2022
(86) PCT No.: PCT/EP2022/084441

§ 371 Date: Sep. 17, 2024

(30) Foreign Application Priority Data
Mar. 17, 2022 (WO) PCT/EP2022/056996
Jun. 9, 2022 (WO) PCT/EP2022/065673

(51) Int. Cl. C23C 16/54; C23C 16/02; C23C 16/24; C23C 16/509; C23C 16/52; H01J 37/32

(52) U.S. Cl. CPC C23C 16/54; C23C 16/02; C23C 16/24; C23C 16/509; C23C 16/52; H01J 37/321

(57) ABSTRACT

The invention relates to a method and to an installation for coating substrates by means of plasma-enhanced chemical vapor deposition (PECVD), in particular for an optionally simultaneous coating of a plurality of substrate surfaces by means of PECVD. A specific arrangement and/or movement of the substrates in a reaction chamber as well as specific operating parameters for the method and/or the installation are also proposed.

### CROSS-REFERENCES TO RELATED APPLICATIONS

This application is a National Stage filing of International Application PCT/EP 2022/084441 (WO 2023/174571) filed Dec. 5, 2022, entitled “METHOD AND PLANT FOR PLASMA COATING” claiming priority to PCT/EP 2022/056996, filed Mar. 17, 2022, and to PCT/EP 2022/065673, filed Jun. 9, 2022. The subject application claims priority to PCT/EP 2022/084441, to PCT/EP 2022/056996, and to PCT/EP 2022/065673 and incorporates all by reference herein, in their entirety.

### BACKGROUND OF THE INVENTION

The present invention relates to the technical field of surface coating of substrates, in particular by means of the method of chemical vapor deposition (CVD). In particular, the present invention relates to the technical field of plasma-enhanced chemical vapor deposition (PECVD).

More particularly, the present invention relates to a method for coating substrates by means of PECVD, in particular for coating a plurality of substrates and/or substrate surfaces.

Furthermore, the present invention relates to an installation and/or coating arrangement for coating substrates by means of plasma-assisted chemical vapor deposition, in particular for coating a plurality of substrates and/or substrate surfaces, and in particular to an installation and/or coating arrangement for carrying out the method according to the invention.

The present invention also relates to the uses described below of the coating process according to the invention and of the installation and/or coating arrangement according to the invention.

In the state of the art, corresponding methods and/or installations are mainly used in manufacturing technology to deposit thin layers of material on the surfaces of workpieces, so-called substrates. Depending on the materials used for the substrate and/or the coating material to be deposited, as well as the purpose of the coating, a variety of different coating processes can be used. At the center point of the present invention is the method of chemical vapor deposition (CVD), in particular in the form of plasma-enhanced chemical vapor deposition (PECVD).

In CVD, a layer of solid material is deposited from a gas phase on the surface of the substrate as a result of a chemical reaction. In order to deposit the corresponding layer component from the gas phase, it is usually necessary to reach a certain reaction temperature. For example, heating the substrate surface is common for this purpose. However, with regard to a coating process that conserves materials and resources, it is sometimes desirable to avoid heating the substrate surface. In such cases, the PECVD method is often used, which is also used in the context of the present invention. Instead of an increased temperature of the substrate itself or in the vicinity of the substrate, a plasma is generated in the reaction chamber, the free electrons and ions of which transfer the necessary dissociation energy to the molecules of the working gas, so that the actual coating material can be deposited from the gas phase.

This method is suitable for a wide range of applications, in particular with regard to the manufacture of electronic components or batteries, in particular batteries based on lithium technology, as well as in semiconductor technology.

From a technical point of view, various plasmas are suitable for the method, which can be generated using a variety of methods. Common forms of plasma include, in particular, DC plasmas, microwave plasmas, capacitively coupled and inductively coupled plasmas.

For example, a high-frequency plasma source is known from EP 1 290 926 B1, in which a choice can be made between capacitive or inductive coupling. In inductively coupled plasmas, the energy required to generate the plasma is provided by means of an induction and/or excitation coil in the form of an alternating electromagnetic field in a gas volume, where the plasma is ultimately built up by accelerating the molecules, atoms and electrons of the gas and the associated impact interactions, in particular impact ionizations, and is maintained by further energy coupling.

When designing an installation for coating processes using the PECVD method, different positioning of the plasma relative to the substrate to be coated is possible. On the one hand, the plasma can be operated at a considerable distance from the substrate. In this case, a working gas flow is usually provided from the plasma to the substrate, by means of which the components of the coating material dissociated in the plasma are transported to the substrate. On the other hand, it is also possible to operate the plasma close to the substrate so that the dissociated coating material components have to travel a comparatively shorter distance to the substrate and diffusion processes, for example, play a greater role in transporting the coating material.

With regard to the time- and cost-efficient use of corresponding installations and methods, it is generally desirable to carry out coating processes as quickly as possible. This is of great importance in particular with regard to applications on an industrial scale, as even slight delays in individual processes can ultimately accumulate over large series of substrates to be coated and thus constitute a considerable cost disadvantage.

In the state of the art, it is also often the case that an increase in the speed of the coating process is accompanied by a significant reduction in the quality of the coating result. This results, for example, in inhomogeneities in the applied material layer, strongly fluctuating layer thicknesses, local defects (i.e. a partially incomplete coating) or the like, which ultimately lead to increased rejects during production or—if further processing goes unnoticed—even to premature failure of the end products with the coated components.

In order to achieve at least a complete coating of the substrate surface, a large amount of coating material is often distributed in the reaction chamber in the prior art, starting from the plasma and/or the precursor gas introduced. In some cases, however, this additionally exacerbates the problem of an uneven layer thickness. Furthermore, it is easy to understand that such an approach is associated with a greatly increased material consumption with regard to the coating material and/or the precursor gas. However, it is generally desirable to achieve the highest possible efficiency in terms of material consumption, not only from a business point of view, but also for reasons of general conservation of resources.

Special solutions that achieve at least acceptable speeds with satisfactory quality results often have the disadvantage that they are only designed for a very specific application. A high degree of flexibility with regard to the type, size and shape of the substrates, which is often desirable in practice, is therefore generally ruled out.

In the state of the art, there is also a lack of higher-level aspects that effectively enable the integration and/or use of a corresponding coating system under the above-mentioned aspects in a (large-scale) industrial context.

In this respect, there is a great overall need for coating processes and corresponding installations and/or coating arrangements with improved properties compared to the state of the art, wherein overall high-performance systems are to be provided which enable excellent speeds with regard to coating processes on substrates, while at the same time guaranteeing a sufficiently high and/or optimum quality of the results achieved.

In particular, it is also desirable to achieve a high level of ergonomics in handling by users, a greatly improved (overall) energy balance compared to the state of the art and increased efficiency of resource consumption overall, as well as a long service life of the material components involved, even with demanding and frequent use.

In particular with regard to industrial-scale applications, there is also a great need for coating processes and corresponding installations that can also be scaled up as far as possible for high throughput rates. Understandably, this places particular demands on the efficiency and energy and/or resource balance to be achieved.

### BRIEF SUMMARY OF THE INVENTION

Against the background of the prior art and in view of the aspects explained above, the object of the present invention is therefore to provide an advanced method for coating substrates and/or substrate surfaces, which method is suitable in particular for the simple, rapid and efficient coating of a large number of substrate surfaces, wherein the disadvantages of the prior art described above are to be avoided as far as possible, but at least mitigated.

In particular, one object of the present invention is to provide a coating process which is improved over the prior art and a corresponding installation and/or coating arrangement which also achieves a high quality of the coating result, in particular with regard to the homogeneity of the deposited layer in terms of composition, density and layer thickness, irrespective of the efficiency achieved.

A further object of the present invention is furthermore to enable the coating of substrates, in particular while ensuring the aforementioned points, also on as different scales as possible, for example on a (large) industrial scale, in a simple and cost-saving manner, and/or to provide a coating process and a corresponding installation which are characterized by a high degree of scalability.

In addition, the handling of the coating process and/or corresponding installations for users, in particular in the practice of commercial users, is also to be optimized with regard to ergonomics, general simplicity and safety. Moreover, the present invention is intended to provide further uses of the coating method or the corresponding installation and/or coating arrangement.

To solve the object described above, the present invention thus provides—in accordance with a first aspect of the present invention—a method for coating substrates by means of plasma-enhanced chemical vapor deposition (PECVD), in particular for preferably simultaneously coating a plurality of substrate surfaces by means of plasma-enhanced chemical vapor deposition; advantageous further embodiments and designs of this aspect of the invention are also discussed.

Furthermore, the present invention—according to a second aspect of the present invention—also relates to an installation and/or coating arrangement for coating substrates by means of plasma-enhanced chemical vapor deposition (PECVD), in particular for preferably simultaneously coating a plurality of substrate surfaces by means of PECVD; further, in particular advantageous embodiments of the installation and/or coating arrangement according to the invention are provided.

In addition, the present invention—according to a third aspect of the present invention—also relates to the use of the corresponding coating system for coating substrates by means of PECVD and/or the use of plasma-enhanced chemical vapor deposition (PECVD) for coating substrates, in particular for preferably simultaneously coating a plurality of substrate surfaces by means of PECVD.

In addition, the present invention—according to a third aspect of the present invention—also relates to the use of the corresponding coating system for coating substrates by means of PECVD and/or the use of plasma-enhanced chemical vapor deposition (PECVD) for coating substrates, in particular for preferably simultaneously coating a plurality of substrate surfaces by means of PECVD.

It goes without saying that in the following description of the present invention, such configurations, embodiments, advantages, examples or the like which—for the purpose of avoiding unnecessary repetition—are set out below only in respect of one individual aspect of the invention, naturally also apply correspondingly to the other aspects of the invention, without the need for express mention.

Furthermore, it goes without saying that in the case of subsequent indications of values, numbers, ranges or the like, the indications of values, numbers and ranges in this respect are not to be understood as limiting; it goes without saying for the skilled person in the art that deviations from the indications or ranges provided may be made on a case-by-case or application-related basis without departing from the scope of the present invention.

In addition, all of the values and/or parameters specified below or the like can in principle be determined or determined using normalized and/or standardized or explicitly provided determination methods or otherwise using determination methods and/or measurement methods familiar to the skilled person in the art in this field. Unless otherwise provided, the underlying values and/or parameters are determined under standard conditions, i.e. in particular at a temperature of 20° C. and/or at a pressure of 1,013.25 hPa or 1.01325 bar. Furthermore, it should be noted that in the case of all the relative and/or percentage, in particular weight-related, quantities provided below, it should be noted that, within the context of the present invention, these figures are to be selected and/or combined by the skilled person in the art in such a way that the total—optionally including further components and/or ingredients—always results in 100% and/or 100% by volume. However, this is also self-explanatory for the skilled person in the art.

Having said this, the present invention will be described and explained in more detail below, also with reference to preferably embodiments and/or examples of embodiments as well as illustrative drawings and/or figures.

In connection with the explanation of these preferably embodiments and/or embodiments of the present invention, which are, however, in no way limiting with respect to the present invention, further advantages, properties, aspects and features of the present invention will also be pointed out.

### BRIEF DESCRIPTION OF THE DRAWINGS

FIG. 1 provides a schematic cross-sectional representation of a part of an installation according to the invention.

FIG. 2 provides an alternative embodiment of the installation of FIG. 5.

FIG. 3 provides another preferable embodiment of the installation according to the invention.

FIG. 4 provides a schematic illustration of a preferable embodiment of a plasma operating device for the method according to the invention in side view.

FIG. 5 provides a perspective view of the plasma operating device of FIG. 1.

FIG. 6 provides a schematic illustration of a further preferable embodiment of a corresponding plasma operating device in side view.

FIG. 7 provides a schematic illustration of a further preferable embodiment of a corresponding plasma operating device in side view.

FIG. 8 provides a schematic illustration of an installation part according to the invention in side view.

FIG. 9 provides a perspective view of the installation part of FIG. 8.

FIG. 10a provides a schematic cross-sectional representation of a part of a further preferable embodiment of the installation according to the invention.

FIG. 11 provides a schematic illustration of a preferable embodiment of a installation part according to the invention.

FIG. 12 provides a perspective view of the installation part of FIG. 11.

FIG. 13 provides a schematic cross-sectional representation of a part of an alternative embodiment of the installation according to the invention.

### DETAILED DESCRIPTION OF THE INVENTION

The applicant has now discovered, in a completely surprising manner, that with respect to a coating method, a sustainable improvement with respect to the underlying properties of such a method—in particular with respect to increased efficiency of resource utilization as well as the scalability of the method—is thereby ensured, that in the context of the present invention a special method for coating substrates by means of plasma-enhanced chemical vapor deposition (PECVD), in particular a method for preferably simultaneously coating a plurality of substrate surfaces by means of plasma-enhanced chemical vapor deposition, is provided,

wherein at least one substrate to be coated is arranged and/or introduced in a preferably closed reaction chamber, in particular in a vacuum chamber, and is subsequently subjected to a coating process, wherein in the coating process a coating material is applied and/or deposited on at least one substrate surface of the substrate, preferably on a plurality of substrate surfaces, of one or more substrates, in particular on two substrate surfaces, of one or more substrates, in particular so that an at least substantially closed and/or at least substantially homogeneous coating is applied and/or deposited on at least one substrate surface, in particular on two substrate surfaces, of one or more substrates, in particular on two, substrate surfaces of one or more substrates, and/or is deposited, in particular so that an at least substantially closed and/or at least substantially homogeneous coating material layer is produced and/or results on the substrate surface to be coated, at least in certain areas, preferably over the entire surface,
wherein silicon is used as the coating material, wherein the coating material is generated from a gas atmosphere which comprises a silicon-containing precursor gas, preferably at least one silane, in particular monosilane (SiH₄), optionally together with at least one inert gas, preferably argon, or consists of a silicon-containing precursor gas, preferably at least one silane, in particular monosilane (SiH₄), by means of at least one inductively coupled plasma (ICP or Inductively Coupled Plasma), in particular generated in situ, wherein the coating material layer is deposited and/or produced as a silicon layer; in particular wherein the silicon layer is deposited and/or produced as a silicon layer.
(i) as an at least essentially amorphous, in particular at least partially hydrogenated silicon layer, or else
(ii) as an at least essentially crystalline, in particular microcrystalline, silicon layer, or else
(iii) as a silicon layer with a crystalline portion and with an amorphous, in particular at least partially hydrogenated portion
   is designed, preferably as an at least essentially amorphous silicon layer, in particular comprising or consisting of hydrogenated amorphous silicon (a-Si:H).

Thus, the present invention is aimed at a specially designed coating method which, due to the targeted combination and sequence of the method steps provided according to the invention, achieves overall improved properties both in terms of increased efficiency of the coating process in particular and of the overall sequence of the method in general, as well as in terms of flexible use and, in particular, a highly pronounced scalability of the method. In this respect, the method steps provided according to the invention and individual facial points of the method designed according to the invention interlock functionally and/or technically and complement each other with regard to the improvements provided beyond the extent of the respective individual steps, so that the special design of the method according to the invention results in an overall synergistic interaction of the individual substeps. According to the invention, a coating process is also provided which allows a rapid coating of a plurality of substrates, but at the same time achieves a high quality of the deposited layer and/or the coated substrates as a whole, which also meets extreme requirements, such as those that exist with regard to the latest semiconductor technology or in the increasingly important field of accumulator production.

According to the invention, it is particularly envisaged that the plasma used in connection with the PECVD method is generated and/or operated as an inductively coupled plasma (ICP). As explained at the outset, such an ICP is generated by inductively coupling energy into a gas volume by means of a high-frequency alternating electromagnetic field. The high-frequency power (RF power and/or often also referred to as RF power for radiofrequency) is generated by means of an excitation coil and/or RF coil in the volume of the plasma and/or in a special plasma operating chamber. This property of an ICP allows a high degree of flexibility with regard to the geometry of a corresponding plasma operating device. As part of the method according to the invention, it is thus possible to respond flexibly to individual application requirements. This ensures that the method always drains optimally in different applications. In particular, the use of an ICP allows the method to be designed in such a way that not only the simplified handling of different substrates and their time-efficient coating but also the flawless production of a high-quality coating material layer on the respective substrate surface is guaranteed.

The particular embodiment of the coating process according to the invention furthermore allows, in particular, a preferred simultaneous coating of a plurality of substrate surfaces. Thereby, it can be surfaces of different substrates and/or several surfaces of one substrate and/or several substrates. Thus, the throughput rate of substrates that can be achieved with the coating process according to the invention is significantly increased, so that applications even on an industrial scale, for example in the series production of components in large quantities, can be easily achieved.

In particular, the choice of silicon as the coating material leads to an extremely uniform silicon layer on the substrate surface according to the method according to the invention with high reproducibility, wherein the silicon is deposited or produced according to one aspect of the present invention as an at least essentially amorphous or at least essentially crystalline silicon layer or as a silicon layer with a crystalline component and with an amorphous component. Here, a coating material layer in the form of hydrogenated amorphous silicon (a-Si:H) or a coating material layer comprising a-Si:H is more preferably used.

In a preferably embodiment of the method according to the invention, the deposited material and/or the material of the coating material layer is also doped. The doping can be carried out by means of post-treatment of the coated substrate surface, for example by ion implantation. Preferably, however, doping already takes place during the deposition of the coating material layer. For this purpose, a doping material is preferably introduced into the reaction chamber as a doping material precursor, in particular in gaseous form. In particular, a separate storage container is provided for the doping material and/or the doping material precursor. The doping material and/or the doping material precursor can be introduced into the reaction chamber together with the coating material precursor, but can also at least partially precede and/or follow the introduction of the coating material precursor.

Metals and/or semi-metals are particularly suitable as doping materials. Boron, among others, has proven to be particularly advantageous and is preferably used as a doping material. In the case of boron, the doping material precursor is present in particular as hydrogen boride, preferably as borane, in particular diborane (B₂H₆).

Alternatively or additionally, the substrate or substrates to be coated can be moved in and/or through the reaction chamber, i.e. in particular in a vacuum chamber, during the coating process. This essentially corresponds to a movement of the substrate or substrates along and/or relative to the at least one inductively coupled plasma. On the one hand, this enables and/or simplifies coating on larger substrates using the method according to the invention. On the other hand, this type of dynamic coating can in many cases produce a significantly more homogeneous coating material layer on the substrate surface compared to a purely static positioning of the substrates in the reaction chamber. Any density gradients in the coating material cloud and/or the coating material flow towards the substrate, which would lead to locally different deposition behavior with a fixed substrate position, are effectively compensated for in this way.

In a preferred embodiment of the method according to the invention, the working pressure set in the reaction chamber and/or in the area of the substrate to be coated during the coating process is in the range from 1×10⁻⁵ mbar to 2 mbar, preferably in the range from 1×10⁻⁴ mbar to 1 mbar, more preferably in the range from 5×10⁻³ mbar to 1×10⁻¹ mbar, especially preferably in the range from 1×10⁻³ mbar to 5×10⁻² mbar. It has been found that a particularly efficient mode of operation can be achieved in these pressure ranges and an ideal distribution of the working gas and/or the coating material in the reaction chamber is achieved. This applies in particular in a vacuum chamber, in which a working pressure in the aforementioned range is set by introducing the precursor gas and optionally other auxiliary gases, in particular noble gases, preferably argon, and/or hydrogen, after a negative pressure or base pressure has been applied.

The gas atmosphere is preferably generated by introducing a working gas stream containing or consisting of the precursor gas, wherein the working gas stream is in the range from 1 sccm to 10,000 sccm, preferably in the range from 10 sccm to 5000 sccm, more preferably in the range from 50 sccm to 3000 sccm, especially preferably in the range from 100 sccm to 2000 sccm. In particular, the composition and/or spatial distribution of the gas atmosphere in the reaction chamber and optionally also the pressure prevailing there can be specifically influenced in this way. The aforementioned working gas flow range has been shown to be particularly suitable for this purpose in extensive tests.

The nature and general quality of the deposited coating material layer can be influenced in particular by the distance of the substrate and/or the substrate surface from the plasma. The distance also has a strong influence on the deposition rate, i.e. the speed at which a certain layer thickness of the coating material layer is produced on the substrate surface. In general, the closer the substrate is positioned to the plasma, the higher the deposition rate. However, if the distance is too small, an irregular layer thickness may be designed and/or inhomogeneities may occur in the layer. If, on the other hand, the substrate is comparatively far away from the plasma, the homogeneity of the layer generally increases, but only low deposition rates are achieved in this case.

As has been found, an average distance of the substrate surface from the plasma in the range from 10 mm to 500 mm, preferably in the range from 20 mm to 300 mm, more preferably in the range from 30 mm to 200 mm, especially preferably in the range from 40 mm to 100 mm, is ideal in order to achieve an optimum compromise between a high deposition rate and good homogeneity of the coating material layer. It should be noted here that the average distance should only be essentially maintained according to the invention. Short-term and/or locally limited deviations, for example due to protruding parts of the substrate or a specific surface profile, do not prevent the generally advantageous effect of a distance in the aforementioned range.

In some cases, the specific shape and/or a comparatively extended, diffuse edge area of the plasma can make it difficult to determine the distance. Usually, the plasma is essentially limited in terms of its spatial extent to a plasma operating chamber of the plasma operating device and its edge areas may protrude a little from this space. In principle, the advantageous effects of the aforementioned distance range can generally be achieved if, as an alternative or in addition to the plasma itself, such a plasma operating chamber is used as a reference for the mean distance to the substrate surface. In particular, a reference plane bounding the plasma operating chamber and defining the distance to the substrate surface is suitable as a reference position, depending on the design of the plasma operating device. In the case of at least essentially flat substrate shapes, an at least essentially parallel alignment of such a reference plane to the substrate surface is advantageous in particular.

In the method according to the invention, the proportion of the coating material generated from the precursor gas that is applied and/or deposited on the substrate surfaces to be coated is, in a particularly advantageous embodiment, at least 10%, preferably at least 15%, more preferably at least 25%, especially preferably at least 30%. This proportion ultimately represents the degree of utilization of the method, so that a high degree of utilization thus leads to a particularly efficient and thus resource-saving mode of operation, in particular with regard to the precursor gas, which usually represents a significant cost item in the implementation of a coating method.

In a particularly preferred embodiment of the method, the degree of utilization and/or the part of the coating material generated from the precursor gas that is applied and/or deposited on the substrate surface to be coated is in the range from 10% to 90%, preferably in the range from 15% to 85%, more preferably in the range from 25% to 80%, especially preferably in the range from 30% to 70%.

The growth rate at which the coating material layer is deposited on the substrate surface is also an essential factor for the speed of the method on the one hand and the homogeneity of the layer produced on the other. As the applicant has determined in extensive investigations, a particularly advantageous compromise can be achieved here if the growth rate is in the optimum range of 1 nm/s to 100 nm/s, preferably in the range of 5 nm/s to 50 nm/s, more preferably in the range of 10 nm/s to 30 nm/s, especially preferably in the range of 15 nm/s to 25 nm/s.

By means of the method according to the invention, it is possible in particular to produce coating material layers with greater layer thicknesses in outstanding quality, in particular with regard to homogeneity and small differences in layer thickness. Larger layer thicknesses are particularly suitable for a large number of special applications, for example in the production of electronic components and in the production of components for batteries and/or accumulators, such as those that are becoming increasingly important in the emerging field of electromobility. Preferably, the coating material layer is deposited and/or produced using the method according to the invention until a layer thickness of at least 0.01 μm, preferably at least 0.1 μm, more preferably at least 1 μm, particularly preferably at least 5 μm, most preferably at least 10 μm, is achieved.

The method according to the invention is particularly suitable for depositing material layers of high layer thickness. Preferably, a maximum layer thickness of 50 μm, preferably 75 μm, more preferably 100 μm, can be achieved.

In order to ensure that no inhomogeneities or other influences and/or undesirable reactions take place or occur on the substrate surface, the gas atmosphere is preferably at least essentially free of oxygen and/or nitrogen. More preferably, apart from any unavoidable traces, neither oxygen nor nitrogen are available in the gas atmosphere. In particular, this prevents the formation of oxides and nitrides, which could impair the coating result.

In particular with regard to a high throughput rate and continuous operation and also with regard to chemical resistance, the reaction chamber, in particular a corresponding vacuum chamber, is at least substantially enclosed by a metallic casing, preferably consisting of stainless steel, or a casing comprising a metal, preferably stainless steel. For cost reasons or to save weight, aluminum can also be used as a material.

A plasma operating device that generates an alternating electromagnetic field by means of an excitation coil or RF coil is used to generate and/or maintain the inductively coupled plasma. The coil may thereby comprise at least one winding by means of which the plasma is supplied with energy when a current flows through the coil winding. In an even more preferably embodiment, the coil may further comprise a plurality of windings. In particular, the windings and/or turns surround a plasma operating chamber, within which the plasma is generated by applying the coil current and consequently the induction of the high-frequency alternating electromagnetic field and maintained after reaching a stable state. In particular, the inductance of the excitation coil and/or its size and/or geometric shape and thus also the shape of the magnetic field can be influenced by changing the number of turns. In this way, it is also possible to flexibly influence the final plasma shape, size and/or position.

The power, in particular RF power, with which the plasma is operated is in particular in the range from 1 kW to 100 kW, preferably in the range from 2 kW to 50 kW, more preferably in the range from 3 kW to 25 kW, especially preferably in the range from 5 kW to 20 kW. On the one hand, this power range ensures stable plasma operation with efficient use of energy, even over longer operating times. On the other hand, the precursor gas supplied can be dissociated particularly efficiently at the aforementioned power levels, so that a high coating material yield is guaranteed.

In other words, the RF power fed into the plasma by the plasma operating device is usually in the range from 1 kW to 100 kW, preferably in the range from 2 kW to 100 kW, more preferably in the range from 3 kW to 25 kW, especially preferably in the range from 5 kW to 20 kW. In particular, the aforementioned power values are to be understood as referring to a single plasma source and/or per plasma operating device. It is understood that in the case of several operated plasmas, different power ratings can also be selected for each plasma source.

Extremely stable operation of the inductively coupled plasma can be achieved in particular at a frequency of the induced alternating electromagnetic field in the range from 2 MHz to 55 MHz, preferably in the range from 5 MHz to 45 MHz, more preferably in the range from 10 MHz to 30 MHz, especially preferably at about 13.56 MHz.

Among other things, the plasma density is also important for the dissociation behavior of the precursor gas and for stable operation of the plasma itself. An average plasma density of the plasma of at least 1×10¹¹ ions/cm³, preferably in the range of 1×10¹² ions/cm³ to 9×10¹³ ions/cm³, has proven to be particularly advantageous for the method according to the invention.

The energy carried by the ions in the plasma is also partly responsible for efficient dissociation of the precursor gas molecules. In corresponding studies, an ideal value for the average ion energy in the plasma has been found to be in the range of 0.5 eV to 60 eV, preferably in the range of 1 eV to 30 eV.

In a preferably embodiment of the method, the plasma is generated and/or operated in a plasma operating chamber which is at least substantially enclosed by the plasma operating device in at least four spatial directions. Preferably, the plasma operating chamber is thereby designed to be at least substantially open to two opposite spatial directions and/or is not enclosed and/or covered by the plasma operating device or parts thereof.

In particular, ring-shaped plasma sources can therefore be used which, from a design point of view, allow a flexible design of the reaction space for the coating process and/or efficient utilization of the available space. “Annular” in the context of the present invention does not exclusively mean the shape of a circular ring, but includes all possible shapes that ultimately form a closed and/or ring-like structure. In general terms, the term “annular” can ultimately be understood to mean any shape that is topologically similar to a torus. In particular, this also includes quadrangular and/or polygonal shapes of a plasma operating device.

Furthermore, it is not absolutely necessary for the method according to the invention that the plasma operating chamber is uncovered over its entire extent in two opposite spatial directions. Depending on the application situation of the method according to the invention, it is also possible, for example, for the plasma operating chamber to be partially covered and/or only partially open in the corresponding directions.

Depending on the subsequent use of the substrates to be coated, a functional pre-treatment of the substrate surface to be coated can be carried out in addition to the coating process, in particular prior to the coating process, at least in certain areas. In particular, methods such as corona pre-treatment and/or plasma pre-treatment, a previous coating with a specific coating material, which does not have to correspond to the coating material according to the process, an etching process and/or, in particular, mechanical surface structuring can be considered. The surface can, for example, be roughened and/or provided with fibers. Such surface pre-treatment can, in particular, promote better adhesion of the coating material layer. Alternatively or additionally, the surface can be given further properties that supplement the properties achieved by the coating according to the process.

One or more carriers, in particular one or more holding frames, can be used to simplify the positioning of the substrate and/or substrates to be coated in the reaction chamber. By means of such carriers, the substrates can not only be brought into an ideal position for coating before the coating process, but can also be held there securely and stably during the coating process in particular. As already explained above, the distance between the substrates and the plasma has a major impact on the success of the coating process. In this context, precise positioning of the substrate at a predetermined point in the reaction chamber before the coating process and/or during the coating process can ensure that a certain distance is maintained exactly.

In a preferably embodiment of the method, at least two substrates are arranged in the reaction chamber. In particular, the arrangement of the substrates relative to one another is such that they are arranged at least substantially parallel to one another in the reaction chamber before and/or during the coating process. In this way, in addition to efficient space utilization within the reaction chamber, uniform coating is also ensured in the same way for both substrates and/or substrate surfaces. It is understood that this arrangement principle can be applied in the same way to a plurality of substrates and, according to the invention, is not limited to two substrates and/or substrate surfaces.

Alternatively or additionally, a plurality of plasmas can also be operated during the coating process. In this case, the plasmas are preferred to be operated in separate plasma operating chambers. In such a case, the arrangement of the plasmas in a preferably embodiment of the method according to the invention is such that the substrate is arranged between the plasmas so that, in particular, coating on both sides can be carried out simultaneously and thus more efficiently. Although it is not absolutely necessary, the several plasmas and/or plasma operating devices are arranged at least substantially identically and/or parallel to each other and/or to the substrate.

It is understood that the term parallel alignment of substrates and/or plasmas with each other and/or with each other refers in each case to the case that the substrates and/or plasmas are extended significantly further in two dimensions than in the third, perpendicular dimension, i.e. that a preferred plane of spatial extension can be defined in each case with respect to the substrates and/or plasmas and/or plasma operating devices. Parallelism may be understood in relation to these preferred planes.

In the case of a plurality of substrates and/or plasmas, an even more preferably embodiment of the method provides for the substrates and plasmas to be arranged in alternating sequence to one another in the reaction chamber before and/or during the coating process. Thus, at least in some areas, one substrate is located between two plasmas and/or vice versa. More preferably, the plasmas and/or plasma operating devices and substrates are aligned parallel to each other and/or to each other. Such a layer-by-layer arrangement can in principle be continued as desired and can therefore also be scaled very well for more extensive coating tasks, for example on a large industrial scale.

In addition to a general movement of the substrate relative to the plasma, the process may also provide for the substrate to be moved in different directions. In particular, a movement in alternating directions and/or an oscillating movement in and/or through the reaction chamber is preferably used. The substrate is preferably moved during the coating process. This also includes movement of the substrate between individual partial coating processes. Thus, for example, a first coating process section can take place first, after which the substrate is moved a little, after which a further coating process section takes place and so on.

Generally formulated, it may be provided that the substrate and/or substrates are moved during a period of time comprising at least the coating process. By moving in different directions, in particular in an oscillating manner, the distribution of the coating material on the substrate surface can be influenced in a particularly targeted and dynamic manner. If the substrate is moved past the same position relative to the plasma and/or a coating material cloud and/or a coating material flow several times in the course of the movement during the coating process, greater layer thicknesses of the coating material layer can thus be achieved in a simple manner, wherein the deposition of the layer takes place with high uniformity and in a homogeneous manner.

Alternatively or additionally, it may be provided that the substrate is rotated during a coating process and/or between several coating processes. In particular, the rotation can thereby take place around a plurality of axes of rotation. This enables, for example, precise positioning and alignment of the substrate as well as uniform coating of different sides of the substrate and/or different substrate surfaces.

In principle, the method according to the invention is suitable for almost any substrate shape or surface shape and/or condition. More preferably, however, the substrate and/or the substrates are such that they comprise at least in some areas an at least essentially flat shape. In particular, particularly suitable substrates can be in the form of a film and/or plate. This is advantageous in particular with regard to the possibility of arranging substrates parallel to one another and/or to correspondingly extended plasmas. Similar advantages with regard to parallelism to other substrates and/or to the plasma arise if the substrate surface to be coated is at least partially flat. This also favors a particularly uniform and homogeneous deposition and/or generation of the coating material layer.

The method according to the invention is also not subject to any fundamental restrictions with regard to the choice of material for the substrate. The substrate can thus comprise, for example, a plastic, a metal, a glass material and/or a ceramic material or consist of a plastic, a metal, a glass material and/or ceramics. In particular, mixed forms and/or composite materials are also possible according to the invention. The embedding of further material components of different composition and/or structure, for example fibers, can also be provided.

In a preferably embodiment of the method, the substrate is present as a roll material, in particular in the form of a film. In this context, it is in particular the case that the substrate is first unrolled from a primary roll before the coating process, in particular outside the reaction chamber, and is fed to the coating process in unrolled, i.e. in particular flat, form. Alternatively or additionally, the substrate can be rolled onto a secondary roll in a corresponding manner after the coating process, in particular outside the reaction chamber. Preferably, a substrate material, in particular in film form, can thus be transported in roll form to the application site of the method according to the invention in a space-saving manner and made available there and/or further transported in a corresponding manner after the coating.

If necessary, for example to promote adhesion of the coating material layer to the substrate surface and/or to positively influence the coating properties, the substrate and/or the reaction space can be tempered at least in certain areas before and/or during the coating process. Here, a temperature of in particular 50° C. to 750° C., preferably from 100° C. to 700° C., more preferably from 200° C. to 650° C., especially preferably from 250° C. to 600° C., is particularly suitable for further optimizing the coating process and leading, for example, to a particularly homogeneous deposited layer.

An additional magnetic field applied in the reaction chamber, in particular in the area of the plasma operating chamber and/or in the area of the substrate, can also be used to influence the ion movement, for example. In addition to additional shaping of the plasma as required, it may also be possible to influence the currents of charged particles in the reaction chamber in a targeted manner in this way. In particular, a magnetic field that is at least essentially constant over time is used for this purpose. In practice, flux densities in the range from 0.1 mT to 200 mT, preferably from 0.2 mT to 100 mT, more preferably from 0.5 mT to 50 mT, especially preferably from 1 mT to 30 mT, have proven to be particularly suitable. Alternatively or additionally, a superimposed electric field can also have a similar effect.

The deposition of the coating material can be supported by biasing the substrate. For this purpose, the substrate is subjected to a positive or negative voltage compared to a neutral potential, so that the coating material molecules or atoms ionized by the plasma follow the resulting potential gradient and are thus increasingly moved to the substrate and deposited on the substrate surface.

In an alternative embodiment of the method, which can be realized alternatively or in addition to the features described above, it is provided that the substrate is moved into and/or through the plasma operating chamber, in particular during the coating process. This procedure is particularly suitable for plasma operating devices that are at least essentially annular in shape and/or for plasma operating devices with a plasma operating chamber that is at least essentially enclosed in at least four spatial directions.

The invention also relates to a corresponding installation for coating substrates by means of plasma-enhanced chemical vapor deposition (PECVD), in particular for carrying out a method of the type described earlier. All the features, properties and advantages of the method according to the invention described above are in this respect to be transferred in the same way to a correspondingly designed installation.

In the following, the method according to the invention and the installation according to the invention are explained in more detail with reference to preferably embodiments. Thereby, all features described and/or shown in the drawings form independent elements of the present invention, irrespective of their combination in the examples shown and/or any references in the claims.

In the figures, it is shown in

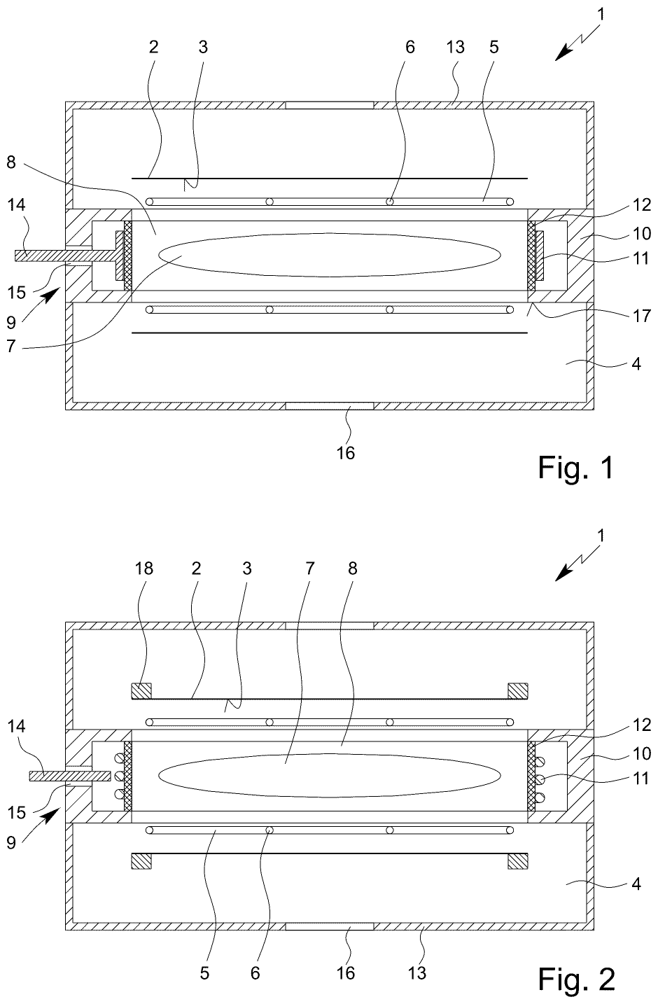

FIG. 1 a schematic cross-sectional representation of a part of an installation according to the invention,

FIG. 2 an alternative embodiment of the installation of FIG. 5,

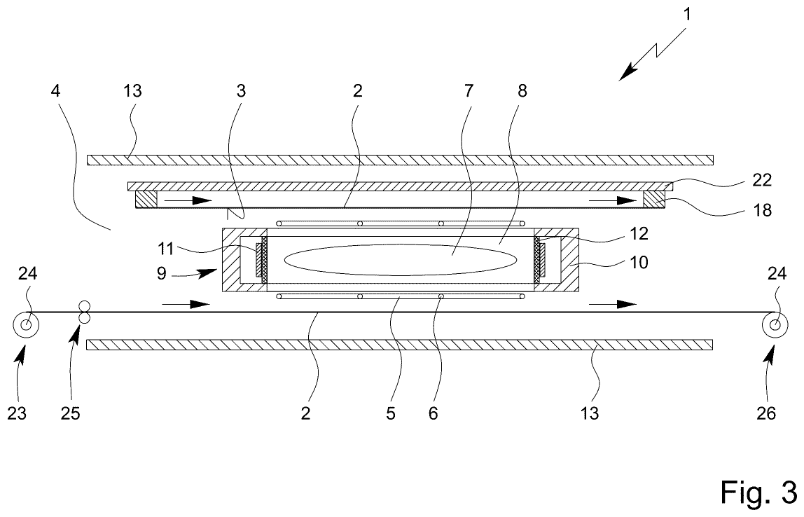

FIG. 3 another preferable embodiment of the installation according to the invention,

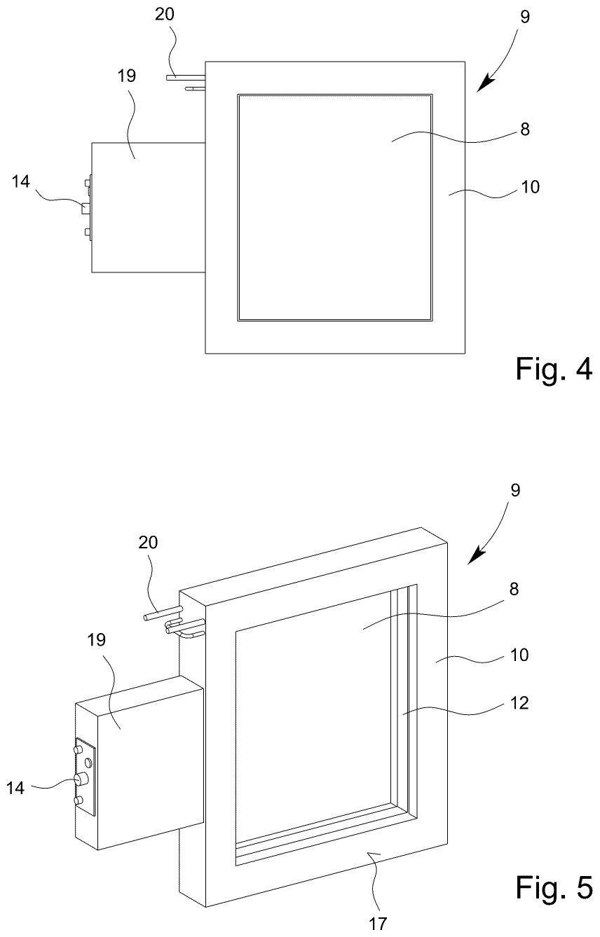

FIG. 4 schematic illustration of a preferable embodiment of a plasma operating device for the method according to the invention in side view,

FIG. 5 a perspective view of the plasma operating device of FIG. 1,

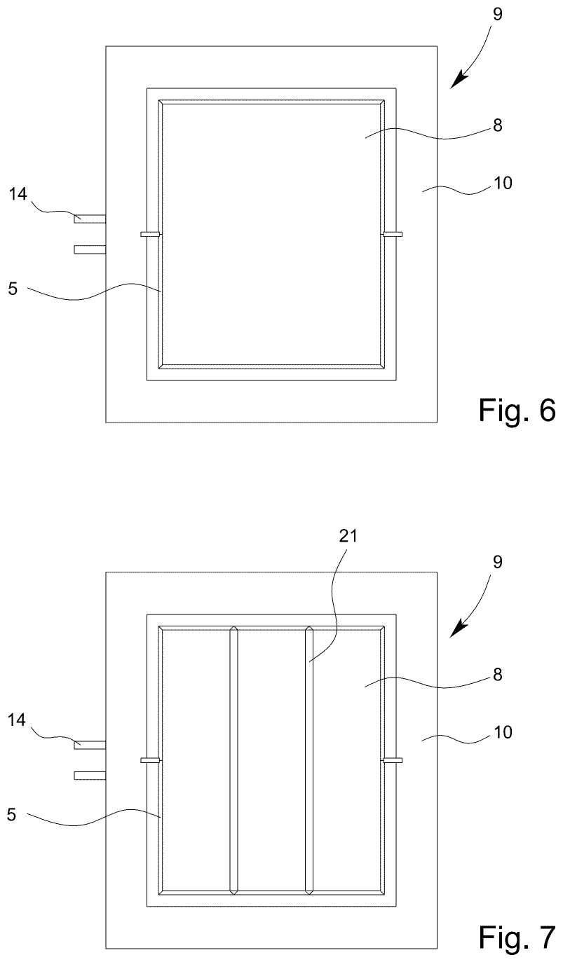

FIG. 6 a schematic illustration of a further preferable embodiment of a corresponding plasma operating device in side view,

FIG. 7 a schematic illustration of a further preferable embodiment of a corresponding plasma operating device in side view,

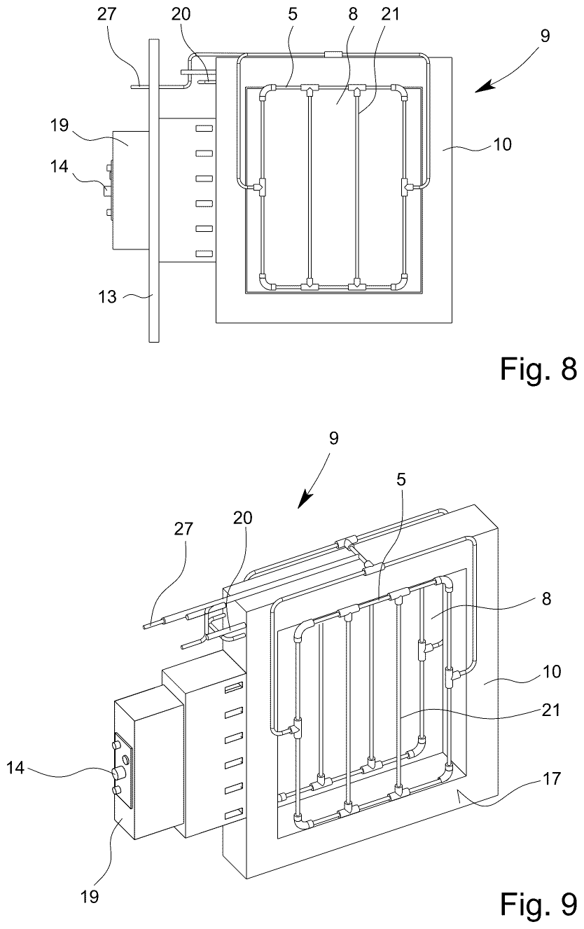

FIG. 8 a schematic illustration of an installation part according to the invention in side view,

FIG. 9 a perspective view of the installation part of FIG. 8,

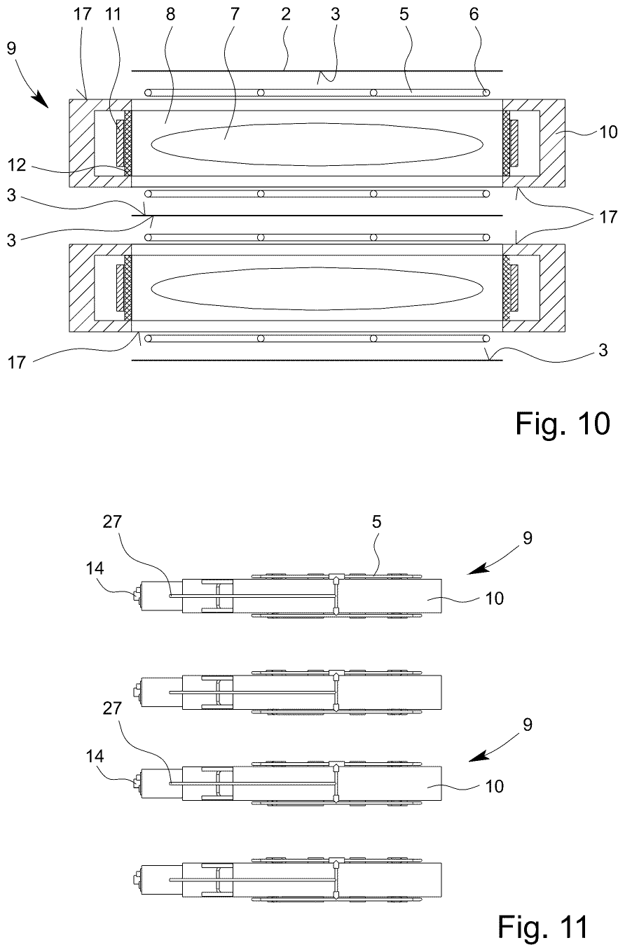

FIG. 10a schematic cross-sectional representation of a part of a further preferable embodiment of the installation according to the invention,

FIG. 11 a schematic illustration of a preferable embodiment of a installation part according to the invention,

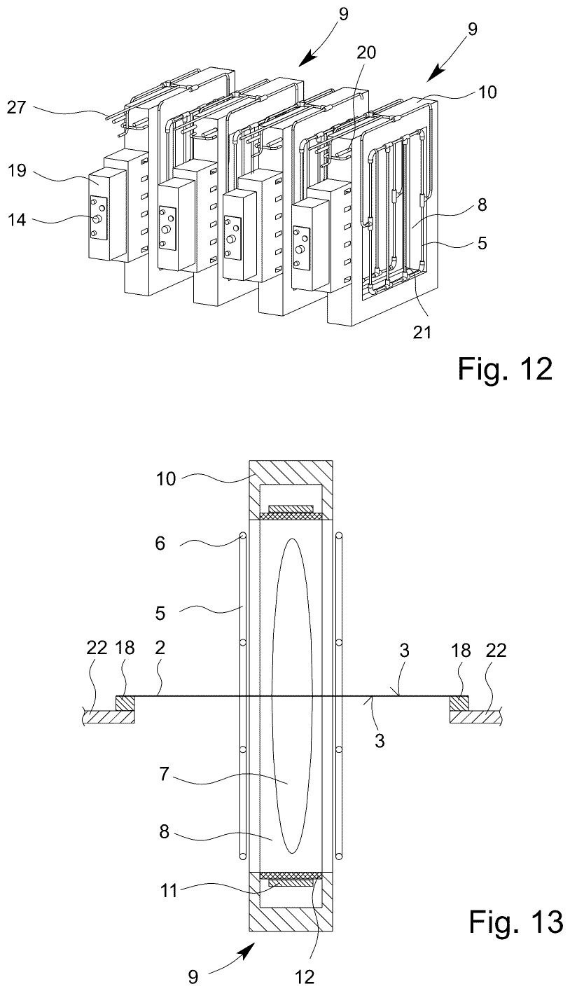

FIG. 12 a perspective view of the installation part of FIG. 11 and

FIG. 13 a schematic cross-sectional representation of a part of an alternative embodiment of the installation according to the invention.

In FIG. 1, the exemplary structure of an installation 1 according to the invention for coating substrates 2 by means of plasma-enhanced chemical vapor deposition (PECVD) is shown schematically in a preferable embodiment. The cross-sectional representation of FIG. 1 thereby corresponds to a typical situation during the execution of a coating process by means of the installation 1 according to the invention.

In the preferably embodiment shown here, two substrates 2 are arranged together in a reaction chamber 4 for coating their substrate surfaces 3.

Gas distributors 5 of a gas supply system are arranged at a comparatively short distance from the substrates 2. A precursor gas can be provided into the reaction chamber 4 from outlet nozzles 6, from which a coating material can be generated for the actual coating process.

In particular, the precursor gas is provided in a storage container, which is not shown in detail for the sake of clarity, and can be supplied from there to the gas distributor 5 via corresponding supply lines, so that the precursor gas ultimately reaches the reaction chamber 4.

In the case of the PECVD method, the coating material is now obtained from the precursor gas by dissociating the precursor gas molecules through the action of a plasma 7. Here, in particular, impact reactions with ions of the plasma take the place of a high temperature of the reaction chamber 4 and/or the substrate 2, which provides the necessary dissociation energy in other coating processes.

In the example shown here, the plasma 7 is generated and/or maintained in a plasma operating chamber 8 of a plasma operating device 9 arranged between the substrates 2.

The plasma operating device 9, which can alternatively also be referred to as a plasma source, preferably has a basic structure, which is shown in FIGS. 4 and 5 in side view and perspective view, respectively, and is also used in the installation situation according to FIGS. 1 to 3.

The plasma operating device 9 has a housing 10, which preferably comprises a shape such that the plasma operating chamber 8 is enclosed on four sides. Such a basically ring-like shape of the plasma source thus preferably has a plasma operating chamber 8 which is open on two sides, in particular opposite sides. From a functional point of view, it is not absolutely necessary for the plasma operating chamber 8 to be completely uncovered on the relevant sides, as in the examples shown. In certain application situations, it may be irrelevant and/or even useful for the plasma operating chamber 8 to be at least partially covered on the sides that are generally kept open so that the plasma 7 is at least partially shielded from the environment outside the plasma operating chamber 8.

The plasma 7 in this case is an inductively coupled plasma (ICP), which is supplied with energy by means of an excitation coil 11. For this purpose, a high-frequency alternating current is applied to the excitation coil 11, which flows through the coil 11. An alternating electromagnetic field is then generated inside the coil 11 and in the plasma operating chamber 8, respectively, which accelerates the gas molecules available there and ionizes them by collisions, which ultimately builds up the plasma and maintains it by continuously coupling high-frequency power (HF power and/or RF power).

In principle, the plasma 7 can be ignited and operated in a working gas, in particular a noble gas, preferably argon. The precursor gas is then fed to the plasma 7. Preferably, however, the plasma 7 is generated and operated at least essentially directly in the precursor gas. Admixtures of other gases, in particular one or more noble gases, preferably argon, are however possible.

Precursor gas molecules in the area of the plasma 7 and/or molecules of the precursor gas that enter the area of the plasma 7 after they have exited the outlet nozzles 6 of the gas distributor 5 are dissociated, in particular by collisions. In the reaction chamber 4, the gas atmosphere set there is thus used to design portions with molecular and/or atomic coating material, which is in this form attached to and/or deposited on the substrate surface 3. In particular, a corresponding coating material layer is deposited on those substrate surfaces 3 that face the plasma 7 and/or the gas distributor 5. However, due to diffusion processes in the reaction chamber 4, the coating material is usually deposited on almost all surfaces in the reaction chamber 4. In addition to the substrate surfaces 3, these include in particular the gas distributors 5, the housing 10 of the plasma operating device 9 and insulators 12, which separate the excitation coil 11 from the plasma operating chamber 8, as well as the inner sides of an outer casing 13 of the reaction chamber 4. of a corresponding coating process with a plurality of substrates 2, which are arranged on opposite sides of a plasma 7 in a common reaction chamber 4, thus leads to a significantly better area yield and thus a higher degree of utilization of the precursor gas with regard to the proportion of the coating material obtained from it that is deposited on the substrate surfaces 3.

In the example shown here, the housing 10 of the plasma operating device 9 forms part of the outer boundary of the reaction chamber 4, in that its outer casing 13 adjoins the housing 10 of the plasma operating device 9. The excitation coil 11 is supplied with electrical current by means of an electrical supply line 14, wherein the electrical supply line 14 is fed into the plasma operating device 9 from the outside through a corresponding feed-through opening 15. Alternatively or additionally and/or in certain areas, the plasma operating device 9 can also be completely accommodated in the reaction chamber 4. In this case, the plasma operating device 9 is also at least substantially enclosed by the outer casing 13 of the reaction chamber 4.

The coating process that is or was in progress can be checked in particular through viewing windows 16. In particular, these can consist of and/or comprise quartz and/or borosilicate glass. The viewing windows 16 are preferably easily removable in the outer casing 13 so that they can be easily removed and replaced for cleaning purposes and/or replaced by new viewing windows 16 in the sense of sacrificial glass if the view into the reaction chamber 4 is too severely impaired as a result of the deposition of coating material on the inside of the viewing windows 16.

The reaction chamber 4 is preferably a vacuum chamber, so that the working pressure inside is comparatively low and/or greatly reduced compared to the ambient pressure. A very low base pressure is initially generated by means of corresponding pumping devices, which are not shown in detail for the sake of clarity. By introducing the precursor gas via the gas distributor 5, a working pressure is then set at which the coating process is carried out.

Operation at a working pressure in the range from 1×10⁻⁵ mbar to 2 mbar, preferably in the range from 1×10⁻⁴ mbar to 1 mbar, more preferably in the range from 5×10⁻³ mbar to 1×10⁻¹ mbar, especially preferably in the range from 1×10⁻³ mbar to 5×10⁻² mbar, has proven to be particularly advantageous for the method according to the invention in the installation 1.

The precursor gas is preferably a silicon-containing precursor gas, preferably at least one silane, in particular monosilane (SiH₄). However, the additional or alternative use of higher silanes, in particular disilane (Si₂H₆), is possible according to the invention.

Optionally, an inert gas, in particular a noble gas, preferably argon, can also be introduced into the reaction chamber 4 via the common gas supply and/or a separate gas distributor 5, resulting in a mixed gas atmosphere with different gas fractions. In particular, a more stable operation of the plasma 7 can be favored by introducing a noble gas. Alternatively or additionally, hydrogen can also be introduced, which is available in the reaction chamber anyway, for example as a result of the dissociation of silane into silicon and hydrogen. Stable plasma operation and the deposition behavior can be influenced in particular by the mixing ratio of the gas fractions.

In a more preferably embodiment, the gas atmosphere provided is at least substantially free of oxygen and/or nitrogen in order to prevent the undesired formation of oxides and/or nitrides. Irrespective of any traces of these elements, some of which are unavoidable, it is more preferably that the gas atmosphere in the reaction chamber 4 contains neither oxygen nor nitrogen.

As mentioned, the gas atmosphere from which the coating material is ultimately obtained by the action of the plasma 7 can be adjusted by a working gas stream containing or consisting of the precursor gas. It has been found to be particularly advantageous for carrying out the method according to the invention and/or operating the installation 1 according to the invention to select such a working gas flow in the range from 1 sccm to 10,000 sccm, preferably in the range from 10 sccm to 5000 sccm, more preferably in the range from 50 sccm to 3000 sccm, especially preferably in the range from 100 sccm to 2000 sccm.

Another parameter that can be used to influence the deposition speed on the one hand and the quality of the deposited coating material layer on the substrate surface 3 on the other hand is the distance of the substrate 2 and/or the substrate surface 3 to the plasma 7. In the case of a plasma 7 that is not clearly defined in the edge area, the plasma operating chamber 8 can alternatively be used as a reference for the distance to the substrate surface 3. In the case of the examples shown here, a reference plane 17 can be defined in this respect, for example, which limits the plasma operating chamber 8 to the sides of the plasma operating device 9 that are open to the outside. In the preferably shown embodiment of the plasma operating device 9, its housing 10 designs an at least substantially flat surface towards the sides in the area which adjoins the open areas of the plasma operating chamber 8. The imaginary reference plane 17 thus extends in the present case over the outer surface of the housing 10 and, starting from this, also continues over the area of the plasma operating chamber 8.

To facilitate the determination of the mean distance between the substrate surface 3 and the plasma 7 and/or the plasma operating chamber 8, but also to achieve the most uniform deposition behavior of the coating material possible, it is preferable that the substrate(s) 2 are arranged parallel to the main expansion plane of the plasma 7 and/or the plasma operating chamber 8, in particular to a corresponding reference plane 17 delimiting the plasma operating chamber 8.

Particularly advantageous results with regard to the compromise between high deposition rate and good quality of the deposited coating material layer, for example with regard to its homogeneity, can be achieved by selecting the distance between the substrate surface 3 and the plasma 7 and/or the plasma operating chamber 8 in the range from 10 mm to 500 mm, preferably in the range from 20 mm to 300 mm, more preferably in the range from 30 mm to 200 mm, especially preferably in the range from 40 mm to 100 mm.

For better handling of the substrate 2, a carrier 18 can be used as shown in FIG. 2, which holds the substrate 2, optionally also several substrates 2, before, during and/or after the coating process in the reaction chamber 4 at a predetermined position relative to the plasma 7 and/or the gas distributor 5. By using such a carrier 18, unnecessary contact with the substrate surface 3 to be coated during handling of the substrate 2 can in particular be avoided. A correspondingly designed carrier 18 can also reduce mechanical stresses on the substrates 2 during positioning and/or as a result of a thermal load before, during and/or after the coating process.

In the exemplary embodiment shown in FIG. 2, an alternative embodiment of an excitation coil 11 is also provided, which surrounds the plasma operating chamber 8 with a plurality of windings. In contrast, the excitation coil 11 shown in FIG. 1 comprises only one turn with which it surrounds the plasma operating chamber 8. Although this is usually sufficient for the application of the method according to the invention and also allows a comparatively simple design of the plasma operating device 9 in terms of construction, the inductance of the excitation coil 11 can be specifically influenced by selecting a higher number of turns, as shown in FIG. 2, for example, whereby the plasma 7 and/or its generation and continuous operation can be positively influenced.

The coupling of a power, in particular high-frequency power (HF power and/or RF power), in the range from 1 kW to 100 kW, preferably in the range from 2 kW to 50 kW, more preferably in the range from 3 kW to 25 kW particularly preferably in the range from 5 kW to 20 kW, has proven to be advantageous for the stable operation of a suitable plasma 7 in the context of the method according to the invention. In particular, the power of the aforementioned range corresponds to the power emitted and/or fed into the plasma by the plasma operating device 9 via the excitation coil 11.

The alternating electromagnetic field generated by the plasma operating device 9 by means of the excitation coil 11 in the plasma operating chamber 8 comprises in particular a frequency in the range from 2 MHz to 55 MHz, preferably in the range from 5 MHz to 45 MHz, more preferably in the range from 10 MHz to 30 MHz, especially preferably about 13.56 MHz.

The outer casing 13 of the reaction chamber 4 preferably consists at least essentially of a metal, in particular stainless steel, or comprises such a metal. This provides the outer casing 13 with a high degree of protection against corrosion and also increased resistance, for example to thermal and/or mechanical loads. In the case of the preferably embodiment of the reaction chamber 4 as a vacuum chamber, this also includes in particular the forces acting on the outer casing 13 due to the internal negative pressure.

The degree of utilization of the installation 1, which is to be understood in particular as the proportion of the coating material generated from the precursor gas which is deposited and/or applied to the substrate surfaces 3 to be coated, is in a preferred embodiment at least from 10%, preferably at least 15%, more preferably at least 25%, especially preferably at least 30%. Specifically, in a further preferably embodiment of the installation 1, it can be provided that the degree of utilization is in the range from 10% to 90%, preferably in the range from 15% to 85%, more preferably in the range from 25% to 80%, especially preferably in the range from 30% to 70%. A high yield of the usually costly coating material can thus be achieved by means of the installation 1 according to the invention.

Alternatively or additionally, the plasma operating device 9 can be designed to enable pulsed operation of the plasma 7. This allows a more precise influence on the operation of the plasma 7 on the coating behavior of the installation 1. In this context, pulsed operation has proven to be particularly advantageous, in which the pulse frequency is in the range from 1 kHz to 100 kHz, preferably in the range from 2 kHz to 50 kHz, more preferably in the range from 2.5 kHz to 10 kHz. In addition, optimization can also be achieved by selecting the relative duty cycle. Regardless of the pulse frequency, preferred values for the relative duty cycle are in the range from 5% to 95%, preferably in the range from 20% to 90%, more preferably in the range from 50% to 85%.

Depending on the application, the excitation coil 11 can also comprise other shapes than the at least essentially cylindrical variants with one or more windings shown here. Alternatively or additionally, it is also possible, for example, to design it at least in some areas as a planar coil and/or as a toroidal coil arrangement, so that adequate coating conditions can be achieved for certain geometries of the reaction chamber 4 and/or substrate shapes.

The plasma operating device 9 usually comprises a control device 19 in the form of a so-called “matchbox”, as can be seen in FIGS. 4 and 5, for example. The control device 19 is used to dynamically adjust the operating parameters of the plasma operating device 9 for stable operation of the plasma 7. In addition to, for example, regulation of the frequency and/or phase of the alternating electromagnetic field, this can include, in particular, power regulation. Application-related adjustments and/or settings of the plasma conditions can be made in a simple and, in particular, dynamically controlled manner using the matching network contained in the matchbox.

Cooling lines 20 can be provided to dissipate the heat associated with the operation of the plasma 7 from the housing 10 and in particular from the excitation coil 11. In particular, flowing a coolant, especially water, through the windings of the excitation coil 11 is an effective way of protecting the system from heat damage. In this case, the internally hollow coil windings themselves form part of the cooling lines 20.

A particularly advantageous dissociation behavior, which is accompanied by an increased provision of coating material from the gas atmosphere in the reaction chamber 4, can be achieved by operating the plasma 7 in which the average plasma density and/or ion density is at least 1×10¹¹ ions/cm³, preferably in the range of 1×10¹² ions/cm³ to 9×10¹³ ions/cm³.

The average ion energy in the plasma 7 is preferably in the range from 0.5 eV to 60 eV, preferably in the range from 1 eV to 30 eV. This also effectively favors the dissociation of the precursor gas.

The installation 1 is preferably designed to produce and/or deposit a layer of coating material with a layer thickness of at least 0.01 μm, preferably at least 0.1 μm, more preferably at least 1 μm, especially preferably at least 5 μm, most preferably at least 10 μm. It is therefore suitable for an extremely wide range of different applications and/or for coating substrates that can subsequently be fed into a variety of different applications.

For high efficiency in terms of time, it makes sense to set the highest possible growth rate. In this respect, the installation 1 according to the invention is designed in particular to produce and/or deposit a coating material layer on the substrate surface 3 at a growth rate of at least 1 nm/s, preferably of at least 5 nm/s, more preferably of at least 10 nm/s, especially preferably of at least 15 nm/s.

However, a compromise often has to be made with regard to a sufficient quality of the coating material layer, which is usually associated with a lower growth rate. Here, a range from 1 nm/s to 100 nm/s, preferably in the range from 5 nm/s to 50 nm/s, more preferably in the range from 10 nm/s to 30 nm/s, especially preferably in the range from 15 nm/s to 25 nm/s, has been found to be the optimum range for the growth rate, in which the installation 1 according to the invention both operates highly efficiently and produces a coating material layer of excellent quality on the substrate surface 3.

The installation 1 according to the invention may further comprise a pre-treatment device by means of which the substrate surface 3 to be coated can be subjected to a functional pre-treatment. This makes it possible to improve the surface properties, for example with regard to optimum adhesion of the coating material during the coating process. In principle, the method according to the invention is suitable for being combined with any pre-treatment process, for example a corona pre-treatment and/or a plasma pre-treatment, a pre-coating with a specific material, in particular a fiber material or a material comprising fibers, an etching process and/or a preferably mechanical surface structuring, in particular by grinding, smoothing and/or roughening. It is understood that corresponding pre-treatments can also be applied only in certain areas, in any combination and/or repeatedly. The installation 1 according to the invention may comprise a corresponding number of pre-treatment devices for this purpose.

Various exemplary arrangements of the gas distributor 5 on the plasma operating device 9 are shown in FIGS. 6 and 7. The embodiment shown in FIG. 6 thereby corresponds to a simple design of the gas distributor 5 as a frame extending in particular along the outside of the edge of the plasma operating chamber 8. The example of a gas distributor 5 shown in FIG. 7 also comprises additional cross struts 21 with their own outlet nozzles 6, which allow the precursor gas to be distributed evenly. It is understood that the gas distributor 5 can in principle be of any complex shape to suit different application situations.

Preferably, the installation 1 further comprises a temperature control device for controlling the temperature of the substrate(s) 2 and/or the reaction chamber 4 to a well-defined temperature. This can further improve the coating process, for example by increasing the adhesion of the coating material and/or supporting the dissociation of the precursor gas. Tempering, in particular pre-tempering, can also reduce the thermal stress to which the substrates 2 are exposed during the coating process, in particular in the vicinity of the plasma 7, as a result of sometimes rapid temperature changes in the environment of the substrates 2. A corresponding temperature control device can be located together with other components of the installation 1 in the reaction chamber 4, but can alternatively or additionally also be arranged outside the reaction chamber 4. Tempering a substrate 2 to a temperature in the range from 50° C. to 750° C., preferably from 100° C. to 700° C., more preferably from 200° C. to 650° C., especially preferably from 250° C. to 600° C., has been found to be particularly suitable for achieving the aforementioned properties in the method according to the invention.

By means of a separate magnetic device, i.e. in addition to the excitation coil 11, a magnetic field can be generated as required in the reaction chamber 4, in particular in the area of the substrate 2, which is at least essentially constant over time and by means of which the movement of the ions and other charged particles can be specifically influenced. In addition to shaping the plasma 7, it is thus possible, for example, to control the particle flow of the coating material. In corresponding experiments, particularly good results were achieved in this respect with a magnetic flux density of the magnetic field of 0.1 mT to 200 mT, preferably from 0.2 mT to 100 mT, more preferably from 0.5 mT to 50 mT, especially preferably from 1 mT to 30 mT. According to the invention, it is possible in this context both to generate such a magnetic field by means of electromagnets and to use permanent magnets with a correspondingly high remanence for this purpose. It is also possible to use a combination of electromagnets and permanent magnets. Alternatively or additionally, a comparable effect can also be achieved by generating an electric field by means of corresponding electrodes, in particular in the area of the reaction chamber 4.

In a more preferably embodiment, which is exemplarily shown in FIG. 3, the installation 1 comprises a movement device 22 for moving the substrate(s) 2 within the reaction chamber 4 and/or through the reaction chamber 4. The movement of the substrate 2 thereby takes place in particular relative to the plasma 7. If the substrate 2 is moved along the plasma 7 in this way, it generally also passes through various areas of the gas atmosphere provided in the reaction chamber 4. Any inhomogeneous distributions of the gas fractions within the gas atmosphere are balanced out by the through movement. A corresponding movement of the substrate 2 also leads to an overall more homogeneous formation of the coating material layer during the coating process. A further significant advantage of moving the substrate 2 in and/or through the reaction chamber 4 is the possibility of serially coating a plurality of substrates 2. In particular, these can be automatically fed into the reaction chamber 4, moved through it and fed out again, wherein they are subjected to the coating process in the reaction chamber 4. As a result, the throughput rate is significantly increased.

As an alternative or in addition to a translational movement of the substrate or substrates 2, the movement device 22 may also be designed to rotate the substrate or substrates 2 in space about one or more axes of rotation. The rotation thereby preferably takes place in the reaction space 4, but can also take place outside the reaction space 4, in particular before and/or after the substrate 2 is provided or diversion. For rotating a substrate 2, the movement device 22 preferably comprises corresponding movement devices, for example grippers, turntables or the like.

The movement device 22 can also be designed, in particular, to first feed the substrates 2 to a pre-treatment device before the coating process in order to subject the substrate surfaces 3 to a functional pre-treatment. The same may alternatively or additionally be provided with regard to any post-treatment of the substrates 2 and/or substrate surfaces 3 after the coating process.

An exemplary embodiment of the installation 1 according to the invention, in which the substrates 2 are moved through the reaction chamber 4 along the plasma 7 and along the gas distributors 5, is shown schematically in FIG. 3. Here, one of the substrates 2 is arranged on a carrier 18, which is moved through the reaction chamber 4 by means of a movement device 22, for example on a rail system.

In the example shown in FIG. 3, a further substrate 2 is present as a film-shaped material, which is first unrolled from a roll 24 by means of an unwinding device 23 and fed to the coating process in planar form after passing through a guide device 25. Alternatively or additionally, after the substrate 2 has been coated, it can be rewound onto a roll 24 by means of a rewinding device 26. The movement device 22 for moving the substrate can, in particular, act on the unwinding device 23 and/or the rewinding device 26 in order to cause the substrate 2 to be advanced through the reaction chamber 4. The movement device 22 and, if necessary, an unwinding device 23, a guide device 25 and/or a rewinding device 26 can be arranged, in particular partially, both inside the reaction chamber 4 and, if necessary, can also be placed outside the reaction chamber 4. Here, tightness requirements of a reaction chamber 4 designed in particular as a vacuum chamber may have to be taken into account. Moreover, it is understood that options for moving substrates 2 can also be combined in ways other than those shown in FIG. 3.

Preferably, the movement device 22 is further designed to move at least one substrate 2 in different directions in and/or through the reaction chamber 4. This not only enables the substrate 2 to be moved along the plasma 7 and/or through the gas atmosphere, but also enables the substrate 2 and/or the substrate surface 3 to be positioned in a targeted manner relative to the plasma 7 in a dynamic manner. As a result, even complexly shaped and/or profiled substrate surfaces 3 can be coated effectively.

By means of an oscillating movement in alternating directions, certain areas of the substrate surface 3, preferably the entire substrate surface 3, can be subjected to the coating process several times, making it easy to realize even greater layer thicknesses of the coating material layer.

FIGS. 8 and 9 each show a part of an installation 1 according to the invention in the form of a plasma operating device 9 with mounted gas distributor 5 and connected control device 19. The control device 19 with the electrical supply line 14 and a gas connection 27 for the gas distributor 5 are in particular routed to the outside through the outer casing 13 of the reaction chamber 4.

According to the invention, it is in particular possible to combine a plurality of plasma operating devices 9 and/or units as shown in FIGS. 8 and 9 and to arrange them in a certain way relative to each other, in particular in a parallel manner as shown in FIGS. 10 to 12. In this way, the installation 1 can be easily scaled for applications of different sizes. The installation 1 is thus preferably designed to operate a plurality of plasmas 7, in particular simultaneously. Thereby, in particular, a plurality of plasma operating chambers 8 are provided, which can be arranged in the reaction chamber 4 according to the application in order to ensure a complete and uniform coating of the substrates 2 and/or substrate surfaces 3.

Furthermore, a plurality of plasmas 7 and/or plasma operating chambers 8 also allow a double-sided coating of a substrate 2 on both opposite substrate surfaces 3. Such a double-sided coating can be carried out simultaneously on both substrate surfaces 3 with the installation 1 according to the invention in a time-saving manner, i.e. without the high apparatus-related effort of turning a substrate 2 between two coating processes being necessary.

An exemplary relative arrangement of the substrates 2 and the plasma operating devices 9 in an example comprising a plurality of both elements is shown in FIG. 10. There, the substrates are designed to be comparatively flat, at least in some areas. In addition, the plasma operating devices 9 are also significantly smaller in one dimension compared to the two other dimensions, which also results in an at least essentially flat shape. In particular, this allows the substrates 2 and/or the plasma operating devices 9 to be arranged parallel to one another and/or among one another. Due to the shape of the plasma operating device 9 and/or the enclosed plasma operating chamber 8, the shape of the plasma 7 during operation is also at least basically predetermined, so that the plasma also preferably extends parallel to the substrate surfaces 3 to be coated.

In the preferably alternating arrangement of substrates 2 and plasmas 7 and/or plasma operating devices 9 shown as an example in FIG. 10, the series can be continued as desired according to the invention and the installation 1 can thus be scaled over a wide range of applications for different scales.

In an even more preferably embodiment shown in FIG. 13, an arrangement of the substrate 2 relative to the plasma 7 and/or the plasma operating chamber 8 is provided in such a way that the substrate 2 is moved through the plasma operating chamber 8 and thus through the plasma 7, in particular by a movement device 22. This can be realized in particular in the case of basically annular plasma sources and/or in the case of plasma operating devices 9 with a plasma operating chamber 8 that is at least substantially enclosed in at least four spatial directions. Thus, the substrate 2 is moved directly into and/or through the spatial regions in the reaction chamber 4 in which the dissociation of the precursor gas takes place, i.e. where there is a particularly high density of the coating material provided. Furthermore, coating of the substrate on both sides is particularly effective in this way.

### LIST OF REFERENCE SYMBOLS

| | |
|---|---|
| 1 | Installation |
| 2 | Substrate |
| 3 | Substrate surface |
| 4 | Reaction chamber |
| 5 | Gas distributor |
| 6 | Outlet nozzle |
| 7 | Plasma |
| 8 | Plasma operating chamber |
| 9 | Plasma operating device |
| 10 | Housing |
| 11 | Excitation coil |
| 12 | Isolator |
| 13 | Outer casing |
| 14 | Electrical supply line |
| 15 | Feed-through opening |
| 16 | Viewing window |
| 17 | Reference level |
| 18 | Carrier |
| 19 | Control unit |
| 20 | Cooling line |
| 21 | Cross brace |
| 22 | Movement device |
| 23 | Unwinding device |
| 24 | Roll |
| 25 | Guiding device |
| 26 | Rewinding device |
| 27 | Gas connection |

1-74. (canceled)

75. A method for coating a substrate by means of plasma-enhanced chemical vapor deposition (PECVD),
wherein at least one substrate comprising at least one substrate surface to be coated is introduced and arranged in a closed reaction chamber, the closed reaction chamber being a vacuum chamber, and is subsequently subjected to a coating process, wherein by the coating process a coating material is applied and deposited on the at least one substrate surface of the substrate such that an at least substantially homogeneous coating material layer is produced on the substrate surface to be coated at least in certain areas,
wherein silicon is used as the coating material, the coating material being generated from a gas atmosphere comprising a silicon-containing precursor gas by means of at least one inductively coupled plasma (ICP), wherein the coating material layer is deposited as a silicon layer on the substrate surface.

76. The method according to claim 75,
wherein the method is performed so as to simultaneously coat a plurality of substrate surfaces, wherein in the coating process the coating material is applied and deposited on a plurality of substrate surfaces of one or more substrates.

77. The method according to claim 75,
wherein the at least substantially homogeneous coating material layer is produced over the entire substrate surface to be coated.

78. The method according to claim 75,
wherein the silicon-containing precursor gas comprises at least one silane in optional combination with at least one inert gas.

79. The method according to claim 75,
wherein the silicon layer is selected to be in the form of:
(i) an at least essentially amorphous silicon layer,
(ii) an at least essentially amorphous, at least partially hydrogenated silicon layer,
(iii) an at least essentially crystalline silicon layer,
(iv) a silicon layer comprising both a crystalline portion and an amorphous portion,
(v) a silicon layer comprising both a crystalline portion and an amorphous, at least partially hydrogenated portion,
(vi) an at least essentially amorphous silicon layer consisting essentially of hydrogenated amorphous silicon (a-Si:H).

80. The method according to claim 75,
wherein the substrate to be coated is moved during the coating process within the reaction chamber relative to the at least one inductively coupled plasma.

81. The method according to claim 75,
comprising a step of simultaneously coating a plurality of substrate surfaces by means of plasma-enhanced chemical vapor deposition (PECVD),
wherein a plurality of substrates comprising at least one substrate surface to be coated is introduced and arranged in a closed reaction chamber, the closed reaction chamber being a vacuum chamber, and is subsequently subjected to a coating process, wherein by the coating process a coating material is applied and deposited on the at least one substrate surface of the plurality of substrates such that an at least substantially homogeneous coating material layer is produced on the substrate surfaces to be coated over the entire surfaces;
wherein silicon is used as the coating material, the coating material being generated, by means of at least one inductively coupled plasma (ICP), from a gas atmosphere comprising a silicon-containing precursor gas comprising at least one silane, wherein the coating material layer is generated in situ and wherein the coating material layer is deposited as a silicon layer on the substrate surfaces;
wherein the silicon layer is selected to be in the form of:
(i) an at least essentially amorphous silicon layer,
(ii) an at least essentially amorphous, at least partially hydrogenated silicon layer,
(iii) an at least essentially crystalline silicon layer,
(iv) a silicon layer comprising both a crystalline portion and an amorphous portion,
(v) a silicon layer comprising both a crystalline portion and an amorphous, at least partially hydrogenated portion,
(vi) an at least essentially amorphous silicon layer consisting essentially of hydrogenated amorphous silicon (a-Si:H);
wherein the substrates to be coated are moved during the coating process within the reaction chamber relative to the at least one inductively coupled plasma.

82. The method according to claim 75,
wherein the coating process is carried out at a working pressure in the range of from 1×10⁻⁵ mbar to 2 mbar and with an average distance from the substrate surface to one of the plasma and a plasma operating chamber in the range of from 10 mm to 500 mm, wherein the gas atmosphere is generated by introducing a working gas stream comprising the silicon-containing precursor gas in the range of from 1 sccm (standard cubic centimeter per minute) to 10,000 sccm (standard cubic centimeters per minute).

83. The method according to claim 75,
wherein the coating process is carried out at a working pressure in the range of from 1×10⁻³ mbar to 5×10⁻² mbar and with an average distance from the substrate surface to one of the plasma and a plasma operating chamber in the range of from 40 mm to 100 mm, wherein the gas atmosphere is generated by introducing a working gas stream comprising the silicon-containing precursor gas in the range of from 100 sccm (standard cubic centimeters per minute) to 2,000 sccm (standard cubic centimeters per minute).

84. The method according to claim 75,
wherein the plasma is generated by an alternating electromagnetic field generated by a plasma operating device, wherein the plasma operating device comprises at least one of an excitation coil and an RF coil comprising at least one turn;
wherein the plasma operating device generates a pulsed alternating electromagnetic field,
wherein the pulse frequency is in the range of from 1 kHz to 100 kHz and
wherein the relative duty cycle is in the range from 5% to 95%.

85. The method according to claim 75,
wherein the plasma is operated with a RF power in the range from 1 kW to 100 kW;
wherein the plasma operating device generates an alternating electromagnetic field with a frequency in the range of from 2 MHz to 55 MHz;
wherein the average plasma density of the plasma is in the range of from 1×10¹² ions/cm³ to 9×10¹³ ions/cm³;
wherein the average ion energy in the plasma is in the range of from 0.5 eV to 60 eV.

86. The method according to claim 75,
wherein, prior to the coating process, the substrate surface to be coated is subjected to a functional pre-treatment selected from the group consisting of a corona pre-treatment, a plasma pre-treatment, a material pre-coating, an etching process, a mechanical surface structuring and combinations thereof.

87. The method according to claim 75,
wherein at least one of the substrate and the reaction chamber is maintained at a temperature of from 50° C. to 750° C.; and
wherein a magnetic field having a flux density of 0.1 mT to 200 mT is generated and maintained in the reaction chamber at least during the coating process.

88. A method for coating a substrate by means of plasma-enhanced chemical vapor deposition (PECVD),
wherein the method comprises simultaneously coating a plurality of substrate surfaces by means of plasma-enhanced chemical vapor deposition (PECVD),
wherein a plurality of substrates comprising at least one substrate surface to be coated is introduced and arranged in a closed reaction chamber, the closed reaction chamber being a vacuum chamber, and is subsequently subjected to a coating process, wherein by the coating process a coating material is applied and deposited on the at least one substrate surface of the plurality of substrates such that an at least substantially homogeneous coating material layer is produced on the substrate surfaces to be coated over the entire surfaces;
wherein silicon is used as the coating material, the coating material being generated, by means of at least one inductively coupled plasma (ICP), from a gas atmosphere comprising a silicon-containing precursor gas comprising at least one silane, wherein the coating material layer is generated in situ and wherein the coating material layer is deposited as a silicon layer on the substrate surfaces;
wherein the silicon layer is selected to be in the form of:
(i) an at least essentially amorphous silicon layer,
(ii) an at least essentially amorphous, at least partially hydrogenated silicon layer,
(iii) an at least essentially crystalline silicon layer,
(iv) a silicon layer comprising both a crystalline portion and an amorphous portion,
(v) a silicon layer comprising both a crystalline portion and an amorphous, at least partially hydrogenated portion,
(vi) an at least essentially amorphous silicon layer consisting essentially of hydrogenated amorphous silicon (a-Si:H);
wherein the substrates to be coated are moved during the coating process within the reaction chamber relative to the at least one inductively coupled plasma;
wherein the coating process is carried out at a working pressure in the range of from 1×10⁻⁵ mbar to 2 mbar and with an average distance from the substrate surface to one of the plasma and a plasma operating chamber in the range of from 10 mm to 500 mm, wherein the gas atmosphere is generated by introducing a working gas stream comprising the silicon-containing precursor gas in the range of from 1 sccm (standard cubic centimeter per minute) to 10,000 sccm (standard cubic centimeters per minute);
wherein the plasma is operated with a RF power in the range from 1 kW to 100 kW;
wherein the plasma operating device generates an alternating electromagnetic field with a frequency in the range of from 2 MHz to 55 MHz;
wherein the average plasma density of the plasma is in the range of from 1×10¹² ions/cm³ to 9×10¹³ ions/cm³;
wherein the average ion energy in the plasma is in the range of from 0.5 eV to 60 eV.

89. An installation for coating substrates by means of plasma-enhanced chemical vapor deposition (PECVD), wherein the installation is configured for simultaneously coating a plurality of substrate surfaces by means of plasma-enhanced chemical vapor deposition,
wherein the installation comprises:
a closed reaction chamber, the closed reaction chamber being a vacuum chamber,
a gas supply for providing a gas atmosphere comprising a silicon-containing precursor gas,
at least one storage container comprising a silicon-containing precursor gas,
at least one plasma operating device for generating and maintaining at least one inductively coupled plasma (ICP) in a plasma operating chamber,
at least one substrate holder and carrier for positioning a plurality of substrates in the reaction chamber,
a movement device for moving the plurality of substrates within the reaction chamber relative to the at least one inductively coupled plasma.

90. The installation according to claim 89,
wherein the installation is configured to generate a working pressure in the range of 1×10⁻⁵ mbar to 2 mbar in the reaction chamber,
wherein the mean distance from the substrate surface to at least one of the plasma and a plasma operating chamber is in the range of from 10 mm to 500 mm, and
wherein the gas supply is configured to generate a working gas stream comprising the silicon-containing precursor gas in the range of from 1 sccm to 10,000 sccm.

91. The installation according to claim 89,
wherein the installation is configured to generate a working pressure in the range of 1×10⁻³ mbar to 5×10⁻² mbar in the reaction chamber,
wherein the mean distance from the substrate surface to at least one of the plasma and a plasma operating chamber is in the range of from 40 mm to 100 mm, and
wherein the gas supply is configured to generate a working gas stream comprising the silicon-containing precursor gas in the range of from 100 sccm to 2,000 sccm.

92. The installation according to claim 89,
wherein the plasma operating device comprises at least one of an excitation coil and an RF coil comprising at least one turn.

93. The installation according to claim 89,
wherein the plasma operating device is configured to generate a pulsed alternating electromagnetic field,
wherein the pulse frequency is in the range of from 1 kHz to 100 kHz, and
wherein the relative duty cycle is in the range of from 5% to 95%.

94. The installation according to claim 89,
wherein the RF power fed into the plasma by the plasma operating device is in the range of from 1 kW to 100 kW; and
wherein the plasma operating device is configured to generate an alternating electromagnetic field with a frequency in the range of from 2 MHz to 55 MHz.

95. The installation according to claim 89,
wherein the average plasma density of the plasma generated by the plasma operating device is in the range of from 1×10¹² ions/cm³ to 9×10¹³ ions/cm³ and
wherein the average ion energy in the plasma generated by the plasma operating device is in the range of from 0.5 eV to 60 eV.
